(19) United States
(12) Patent Application Publication
(10) Pub. No.: US 2015/0259825 A1
(43) Pub. Date: Sep. 17, 2015

(54) METHOD AND APPARATUS FOR THE FABRICATION OF NANOSTRUCTURES, NETWORK OF INTERCONNECTED NANOSTRUCTURES AND NANOSTRUCTURE

(71) Applicant: MAX-PLANCK-GESELLSCHAFT ZUR FÖRDERUNG DER WISSENSCHAFTEN E.V., Munich (DE)

(72) Inventor: Zumin Wang, Stuttgart (DE)

(73) Assignee: MAX-PLANCK-GESELLSCHAFT ZUR FÖRDERUNG DER WISSENSCHAFTEN E.V., Munich (DE)

(21) Appl. No.: 14/424,633

(22) PCT Filed: Sep. 4, 2013
(86) PCT No.: PCT/EP2013/068252

§ 371 Date: Feb. 27, 2015

Related U.S. Application Data
(63) Continuation-in-part of application No. PCT/EP2012/067183, filed on Sep. 4, 2012.

(51) Int. Cl. C30B 25/08; C30B 25/18; C30B 25/04; C30B 25/10

(52) U.S. Cl. CPC C30B 25/08; C30B 25/10; C30B 25/18; C30B 25/04

(57) ABSTRACT

The present invention relates to a method for the fabrication of nanostructures, comprising the steps of: a) providing a substrate having a polycrystalline film on at least a surface thereof, wherein the polycrystalline film is a film having grain boundaries; and b) exposing the polycrystalline film to a vapor flux at a temperature equal to or above ambient temperature, wherein at least one element which is included in the vapor diffuses into the grain boundaries of the polycrystalline film resulting in growth of nanostructures at said grain boundaries. The invention further relates to a network of interconnected nanostructures, to a nanostructure, as well as to an apparatus for the fabrication of nanostructures and networks of interconnected nanostructures.

The present invention relates to a method and to an apparatus for the fabrication of nanostructures, to a network of interconnected nanostructures and to a nanostructure.

Nanostructures, such as nanowires have numerous potential applications in many fields of technology, for example, in the fields of nanoelectronics, flexible electronics, photonics, sensors, and in energy harvesting and storage devices. A study performed by C. K. Chan et al. published in Nature Nanotechnology 3, 31 (2008) with the title “High-performance lithium battery anodes using silicon nanowires” discusses a recent breakthrough and demonstrates that an advanced lithium-ion battery using silicon nanowires as the anode material has a much higher electrical storage density than existing lithium-ion batteries.

A further example is a novel solar-cell design on the basis of silicon nanostructures which has achieved a 96% peak absorption efficiency of sunlight, while using only 1% of the silicon material required in conventional silicon solar cells. This work was published by M. D. Kelzenberg et al., in Nature Materials 9, 239 (2010) with the title “Enhanced absorption and carrier collection in Si wire arrays for photovoltaic applications”. It is thought that nanostructures are a promising starting basis for solving a series of key technological issues and can serve as major building blocks in advanced fields of technology.

Unfortunately the use of nanostructures on a large, industrial scale has been hindered in practice by their high production cost. The predominant method of production of nanostructures is still based on a process that was first described in 1964 by R. S. Wagner and W. C. Ellis, in the publication titled: “Vapor-liquid-solid mechanism of single crystal growth”, published in Appllied Physics Letters 4, 89 (1964).

The so-called vapor-liquid-solid (VLS) growth process utilizes tiny particles of metal catalysts as seeds for the growth of the nanostructures. The metal seeds are deposited on a solid substrate, melted by heating and then exposed to a gas atmosphere containing source materials of the semiconductor (e.g. silicon and germanium). The metal droplets then take up semiconductor atoms from the gas until they are supersaturated, and the excess semiconductor material precipitates at the boundary with the substrate: causing a nanostructure to grow.

Gold is typically used as a catalyst because it is capable of dissolving silicon or germanium when molten. The use of this expensive catalyst and the high process temperatures typically in the range of from 600 to 900° C. lead to very high production costs. The required high process temperature also necessitates the use of expensive heat-resistant substrates (such as sapphire) for the process, further increasing the production costs. Last but not least, the VLS growth method is a very delicate process which requires a very accurate control of the size of the metal catalysts (of the order of tens of nanometers), the gas flow and pressure, and a (uniform) substrate temperature, which makes it extremely difficult to scale the VLS process up to a large, industrial scale.

The publication by Zumin Wang et al., published in Advanced Materials 23, 854-859 (2011) reported the discovery of a growth mechanism for growing silicon nanowires in solid amorphous-silicon/aluminum (a-Si/Al) bilayers. This was effected by in situ transmission electron microscopy experiments. Although the discovered mechanism allows the growth of silicon nanowires at relatively low temperatures, the approach with solid bilayers has serious drawbacks, which retard the industrial application of it.

In the growth process reported by Wang et al. an aluminium layer is initially coated with an a-Si layer to form an a-Si/Al bilayer. Following this the bilayer is heated to an elevated temperature so that the Si atoms present in the a-Si layer are transported towards the Al grain boundaries present in the aluminium layer along the solid a-Si/Al interface. The diffusion of Si atoms along the solid a-Si/Al interface is very slow, so that effectively only the a-Si material in the vicinity of the Al grain boundaries is consumed for growth of a Si nanowire. The bulk of the solid a-Si, however, remains on top of the Al layer after the growth of Si nanowires. The fact that the nanowires are grown from the material present in the a-Si layer means that the nanowires are inherently connected to the bulk a-Si layer, making it very difficult to separate the nanowires from the remaining a-Si layer, retarding further applications of these nanowires. The remaining large amount of unreacted a-Si leads to a fairly large waste of source materials and therefore to an unacceptable low productivity yield of nanowires using this reaction.

Furthermore, owing to the depletion of a-Si material in the a-Si layer near the Al grain boundaries, the growth of Si nanowires always terminates without the complete grain-boundary network being utilized in the aluminium. This means that the grown Si nanowires are not laterally interconnected and do not grow to their full possible size.

In view of the above it is an object of the invention to provide an alternative method of fabrication of nanostructures which is less expensive in use, permits better reproduction of the fabrication results and allows an industrial scale production of nanostructures to take place, as well as to provide a beneficial network of interconnected nanostructures and an expedient nanostructure.

This object is satisfied by a method of fabrication in accordance with claim 1, by a network of interconnected nanostructures in accordance with claim 19, by a nanostructure in accordance with claim 32, and by an apparatus in accordance with claim 33.

In particular the method for the fabrication of nanostructures, comprises the steps of:

a) providing a substrate having a polycrystalline film on at least a surface thereof, wherein the polycrystalline film is a film having grain boundaries;

b) exposing the polycrystalline film to a vapor flux including at least one element, at a temperature equal to or above ambient temperature, wherein at least one element included in the vapor diffuses into the grain boundaries of the polycrystalline film resulting in the growth of nanostructures at said grain boundaries.

In this connection it should be noted that the polycrystalline film can be deposited onto the substrate using known techniques, such as physical vapor deposition (PVD) or chemical vapor deposition (CVD), in which a desired material composition is evaporated in a vacuum chamber and is directed at the substrate to be coated in order to form a film thereon. The vapor including the at least one element can also be provided using a CVD or PVD device. In this connection the coated substrate is then exposed to the vapor including the at least one element, so that this can diffuse into the grain boundaries of the polycrystalline film resulting in the growth of nanostructures at said grain boundaries.

The method utilizes the fact that the diffusion of atoms (e.g. C, Al, Si, Ge) along a free surface (i.e. surface diffusion) is very fast even at low temperatures. The atoms from the vapor flux may readily diffuse over a relatively long distance along the film surface towards the grain boundaries in the polycrystalline film, leading to the growth of nanostructures along the grain-boundary network in the polycrystalline film. Since the method in accordance with the invention can be carried out at lower temperatures cheaper substrates can be used during the growth process significantly reducing the cost of manufacturing nanostructures.

In contrast to Wang et al., one can, for example avoid the occurrence of any amorphous semiconductor remnants in connection with the grown semiconductor nanostructures, by using the method disclosed in the present invention. Avoiding the occurrence of any amorphous semiconductor remnants advantageously allows the nanostructures to be separated from the growth material.

Moreover, a high molar production yield (70%-100%) of nanostructures (defined as the ratio of the material in the produced nanostructures and the consumed source material) can be reached. Furthermore, because of the continuous and manageable supply of the source material (in vapor) towards the polycrystalline film surface, the nanostructure grows along the complete grain-boundary network in the polycrystalline film, and thus a continuous network of interconnected nanostructures (further referred to as a nanostructure network) can be produced. Such nanostructure networks can enable novel, advanced applications in e.g. filtration devices, chemical or biological sensing devices, medical devices, or nanoelectronic devices.

In addition to the advantageous aspects discussed above, the method disclosed in the present invention has a series of decisive advantageous aspects which are of critical importance for industrial applications.

For example, the method allows an accurate and flexible doping of semiconductor nanostructures and networks of interconnected nanostructures during their growth using different doping types and doping concentrations, by introducing certain amounts of dopant vapors (e.g. phosphor, PH₃, B₂H₆) together with a semiconductor source vapor. Doping of semiconductor nanostructures is required in many potential fields of application, such as in the fields of (nano)electronics, optoelectronics, sensors, solar cells, and photoelectronchemistry devices.

The disclosed method operates at very low process temperatures and at very high nanostructure production speeds. For example a silicon nanostructure network was prepared at about 90° C. with a growth time of 210 seconds by means of the disclosed method. Such temperatures advantageously allow a very broad choice of the heat-sensitive substrate (e.g. various polymers or polymer films can be used as substrates), and much lower production costs.

A further advantageous aspect exists in that the disclosed method is fully compatible with large-area PVD and CVD equipment (also plasma enhanced PVD and CVD can be used). Such PVD and CVD equipment is intensively used in current semiconductor manufacturing plants, solar-panel plants, and in the packing industry. Therefore the disclosed method can be straightforwardly used and/or integrated into existing plants and especially into existing manufacturing steps for large-volume manufacturing of nanostructures, networks of interconnected nanostructures, and advanced devices on the basis of the nanostructures and the nanostructure networks.

The present invention is directed to overcoming the high-cost and non-scalable issues in producing nanostructures, and provides a low-temperature, easy-to-use and scalable solution for cost-effective production of nanostructures. For example, the disclosed method allows the production of semiconductor nanostructures at a processing temperature which is no higher than 600° C. (typically at ambient temperature to 200° C.), and in which the use of expensive catalysts such as gold is not required. The method is further compatible with major existing equipment and facilities in current semiconductor industries, in solar-panel plants, and in the packing industry, and can readily be scaled up to an industrial level.

In an embodiment of the method, the substrate is selected from the group comprising polymers, polymer films, plastics, plastic films, semiconductor substrates, glasses, oxides, ceramics, metals, metal alloys, metal foils and metal alloy foils.

Such substrates are more versatile in use and cheaper than e.g. sapphire which was previously used in order to grow nanostructures according to the VLS method.

In a further embodiment of the method, the polycrystalline film is a pure metal or a metal alloy film, preferably containing at least one element selected from the group comprising Al, Ti, Cr, Mn, Fe, Co, Ni, Cu, Zn, Zr, Nb, Mo, Pd, Ag, In, Sn, W, Pt, Au and Pb.

Selecting and processing appropriate materials permits the grain structure of the polycrystalline metal or metal alloy film to be successfully manipulated. Nanostructures of desired morphology can thus be manufactured by controlling the polycrystalline film structure by selecting and processing the metal and/or alloy film provided on top of the substrate. This is because different films have different microstructures leading to different morphologies of the grain boundary network being present in the film. This means that using certain types of metal or metal alloy films leads to a certain grain structure being present in the film, and the nanostructures grown in the film will then adopt the morphology of the grain structure of the provided polycrystalline film.

In an alternative embodiment the thickness of the polycrystalline film is less than 1 μm and preferably less than 100 nm and is most preferably greater than or equal to 5 nm.

By selecting the thickness of the polycrystalline film one inherently determines the height of the nanostructures and nanostructure networks to be grown by the described method. The selected thickness of the polycrystalline film also has an influence on the time needed for the growth of nanostructures and nanostructure networks in the polycrystalline film, which for growth in a 10 nm thick polycrystalline film is preferably in the region of 1 to 60 seconds and for growth in a 50 nm thick film lies in the region of 5 seconds to 50 min, preferably in the region between 10 seconds to 10 min. Such growth times of nanostructures permit growth of nanostructures at industrially acceptable times.

In yet another embodiment the method is carried out at a temperature in the range of the ambient temperature to 600° C., and preferably at a temperature in the range of from ambient temperature to 350° C.

Such temperatures make the method more cost effective since lower temperatures permit cheaper materials to be used as substrates and reduce the cost of the growth method. Selecting the appropriate growth temperature can also influence the growth times of the nanostructures in order to obtain a good growth rate. The temperature range at which a good balance is found between growth rate and stability of the process, i.e. a good reproducibility of the process, is found at a temperature range of from ambient temperature to 350° C. This temperature range is significantly below the previously known temperature ranges. In particular on comparing the temperature ranges specified here with the temperature used in the VLS method, it has been found that nanostructures can now be grown at temperatures where nanostructures could not previously be grown.

In another embodiment the said vapor contains, preferably at least one, element(s) selected from the group comprising group III elements (e.g. B, Al, Ga, In), group IV elements (e.g. C, Si, Ge, Sn, Pb), group V elements (e.g. N, P, As, Sb, Bi), O, S, Cu, Zn, Pd, Ag, Pt and Au.

In principle any material can be selected as the material of the vapor, as long as it can be provided in vapor form and is capable of industrial application. For example, the disclosed method also allows the growth of alloy semiconductors (such as SiₓGe₁₋ₓ) or compound semiconductors (such as GaAs) nanostructures and nanostructure networks, with tailorable composition, by simultaneously introducing different types of vapor with different flux ratios.

In a further embodiment the vapor flux is restricted to below a level at which the material of the vapor is deposited as a film on the free surface of the polycrystalline film. This means that the vapor flux should not be so high that a film comprising the vapor material is grown on the free surface of the polycrystalline film and even over the complete surface of the polycrystalline film, since this would lead to a deficient growth of the nanostructures in the grain boundaries of the polycrystalline film.

If the surface is coated with a further film this can clog up the grain boundaries leading to a reduced diffusion rate which slows down the growth process and reduces the quality of the nanostructures grown. Therefore appropriate selection of the vapor flux is desired and vapor flux rates typically in the range of 10⁻⁹ to 10⁻³ mol·m⁻²·s⁻¹ and preferably in the range of 10⁻⁸ to 10⁻⁴ mol·m⁻²·s⁻¹ are selected.

The method advantageously allows the precise management and adjustment of the vapor flux (J_{V}) supplied in the direction of the polycrystalline film surface. By adjusting J_{V} to be smaller than the maximum total diffusional flux of the material of the vapor along the grain boundaries (ΣJ_{GB}) in the polycrystalline film, the occurrence of layer growth above the polycrystalline film surface can be largely/absolutely avoided during the growth of the nanostructures in the grain boundaries of the polycrystalline film.

In a further embodiment, in step b, at least one element included in the vapor flux diffuses into the grain boundaries of the polycrystalline film and reacts with the polycrystalline film to form compound nanostructures or alloy nanostructures at the grain boundaries. Thereby further specific types of nanostructures can be grown, which not only have a tailorable structure and morphology, but also have specific tailorable chemical compositions.

In a preferred embodiment the material of the vapor flux diffuses into the grain boundaries of a polycrystalline metal or metal alloy film which is on a polymer/plastic substrate like Polyethylene (PE), Polyethylene terephthalate (PET), Biaxially-oriented polyethylene terephthalate (BoPET, e.g. Mylar), Polyimide (PI, e.g. Kapton), Polyamide (e.g. Nylons) or Polycarbonate (PC).

When the element of the vapor flux grows as nanostructures in the polycrystalline metal or metal alloy film, the mechanical properties of the film, including hardness, modulus, stiffness and wear resistance, can be enhanced. Such low-temperature (compatible with polymers/plastics) reinforced films can beneficially be used e.g. in the manufacture of metallized plastics or metallized polymer films which can be used in applications, such as automotive trim, aerospace applications, decorative applications, e.g. mobile phone covers, packaging (food, pharmaceuticals, electronics) or even for insulation purposes etc. U.S. Pat. No. 5,942,283 discloses a method and an apparatus for fabricating a metallized film, whose contents are hereby incorporated by reference. The method of manufacture uses an evaporation source in order to deposit a metal layer on a plastic film. The manufacture of reinforced metallized polymer or plastic films according to the invention can, for example, be achieved by including a second vapor source downstream of the metal evaporation source for generating the polycrystalline film.

In a different embodiment the method further comprises the step of thermal, mechanical, or plasma treatment of the polycrystalline film before step b. Such a treatment may be used to tailor the grain structure (i.e. grain boundary network structure) of the polycrystalline film. As a result, the morphology of the nanostructures and the network of interconnected nanostructures, which form along the grain boundary network of the polycrystalline film, can be tailored and/or manipulated by a corresponding treatment of the polycrystalline film.

An example of a thermal treatment process is to heat the substrate/polycrystalline film to an elevated temperature sufficient to cause the internal structure of the polycrystalline film to change, e.g. at elevated temperatures in the range of from 100 to 600° C. The heating causes the internal structure of the polycrystalline film to change which brings about a change in the grain structure (e.g. grain sizes and grain-size distribution) of the polycrystalline film and hence of the nanostructures grown therein.

In a further preferred embodiment of the method, during step b, at least two elements included in the vapor flux diffuse into the grain boundaries of the polycrystalline film. Depending on the choice of elements this results in the growth of alloy nanostructures (for example, using two elements which form an alloy), compound nanostructures (for example, using two elements which react to form a compound) or doped nanostructures (for example, using a semiconducting element and a dopant element) at the grain boundaries.

In yet another preferred embodiment of the method, at least one of the elements diffusing into the grain boundaries in step b is a dopant element. Thereby doped nanostructures can be formed at said grain boundaries.

In a preferred variant of the method, during step b, after deposition of the at least one material at the grain boundaries at least one further material is deposited on top of the at least one material, optionally in the same treatment chamber or in a second treatment chamber. For this purpose, the polycrystalline film is sequentially exposed to at least two different types of vapor flux, i.e. nanostructures comprising two or three or more layers of respectively different material types or compositions can be grown in a grain boundary of the polycrystalline film.

By providing several types of layers on top of one another, p-n, n-p, p-i-n, or n-i-p type nanostructures can be grown which could be advantageously used in nanoelectronic devices.

The disclosed method therefore further allows the growth of semiconductor nanostructures and nanostructure networks comprising dopant-modulated heterostructures (such as p-n diodes and field-effect transistors), by simply alternating the concentrations and types of the dopant vapor introduced. By alternating the material types of the vapor introduced, nanostructures and nanostructure networks comprising composition-modulated heterostructures (e.g. Si/Ge heterojunctions) can also be grown.

In a further embodiment the method comprises the step of removing said nanostructures from said substrate.

Removing the nanostructures and the nanostructure network from the substrate either on their own or with the polycrystalline film leads either to free nanostructures which can be used e.g. in electronic devices or to reinforced films which can be used for further applications.

In yet a further embodiment the method comprises the step of selectively etching off the polycrystalline film. This advantageously leads to either a nanostructure network which is standing on the substrate or a freestanding interconnected web of nanostructures (further referred to as a nanowire nanomembrane, or a nano net).

If the nanostructure network is standing on the substrate, a metal substrate could be chosen as the substrate and in this way act as a contact for an electronic device. The then free end of the nanostructure network could also be provided with a contact to fabricate e.g. a p-n junction if a multilayered nanostructure was grown. The substrate having such a web of interconnected nanostructures grown thereon could be separated into a plurality of nanostructures for further types of application.

In the event that the nanostructure network is separated from the substrate, the nanostructure network can be transferred to other substrates for further applications. The nanostructure network can also be divided into a plurality of individual nanostructure networks which can be used in further applications, e.g. as the filter material of filter devices or as the nanoporous material in nanopore-based biosensing devices.

In a preferred embodiment the polycrystalline film is selectively masked to define at least a first exposed region and at least one second masked region, a first vapor having a first composition is allowed to be exposed to the polycrystalline film at the first exposed region causing growth of nanostructures of a first composition at the first exposed region, the second masked region is at least partly exposed to form a second exposed region and a second vapor having a second composition is allowed to be exposed to the polycrystalline film at the second exposed region causing growth of nanostructures of a second composition at the second exposed region.

Thereby e.g. an n-p structure can be grown not only in accordance with the thickness of the polycrystalline film, but also along the length of the film in order to grow very thin lateral n-p structures, i.e. structures having a height in the size range of the thickness of the film which can be e.g. 10 nm to 100 nm. Using several different exposed and/or masked regions also enables the growth of lateral e.g. n-i-p, p-i-n, n-i-p-i-n-i-p, or Ge—Si—Ge heterostructures etc. in the nanostructure network plane.

In a preferred embodiment of the method this further comprises the step of, following the etching off of the polycrystalline film, providing a further coating on the network of interconnected nanostructures standing on the substrate or on the freestanding network of interconnected nanostructures, leading to a coated network of interconnected nanostructures. Such a coating can be provided e.g. by means of one of the following methods: PVD, CVD, atomic layer deposition and plating.

In this way, for example, an electrically conductive network of interconnected nanostructures is generated by coating a semiconductor or insulator nanostructure network with a conductor material (e.g. Ag, Au, Al, Cu, graphite, graphene, Pd, Pt, Ni, Ti, Co, W, Zr, Hf, Ta, Mo), which can advantageously be applied as a transparent conductive electrode, for example, in displays and solar cells.

In a further embodiment of the method this comprises a further step of subjecting the coated network of interconnected nanostructures to a heat treatment step to form a compound nanostructure network composed of the nanostructures and the material of the further coating. This means that, due to the thermal treatment, a reaction between the original nanostructure network (of e.g. Si, Ge) and the coating material (of e.g. Ni, Cu, Co, Ti, W), is allowed to thus form a compound (e.g. Ni silicides, or other metal silicides or germanides) nanostructure network. Such a compound (in particular, metal silicides) nanostructure network can also advantageously be applied as a transparent conductive electrode in, for example, displays and solar cells.

In yet another preferred embodiment of the method this comprises the step of, following the etching off of the polycrystalline film, functionalizing the surface of the network of interconnected nanostructures standing on the substrate or the freestanding network of interconnected nanostructures (e.g. of Si) with chemical layers (e.g. amino-silanes, alkane-silanes, or aldehyde-silanes), biological receptors (e.g. biotin, antibodies), or metal (e.g. Ag, Pd, Pt) nanoparticles, leading to a surface-functionalized network of interconnected nanostructures. The functionalization advantageously permits the network of interconnected nanostructures to be used in sensing devices for (ultra-)sensitive detection of gases (e.g. hydrogen, CO, ammonia), chemical or biological (e.g. proteins, drug molecules) species.

In a further aspect the invention relates to a network of interconnected nanostructures, in particular formed in accordance with the method in accordance with the invention.

In one embodiment the network of interconnected nanostructures is provided as a freestanding network of nanostructures, i.e. the main surfaces of the freestanding network of nanostructures are no longer in contact with any further material (i.e. as an ultrathin porous membrane, or a nanowire nanomembrane, or a nano net). This means that the network of interconnected nanostructures can subsequently be obtained in which the substrate and the polycrystalline film are removed. Such a freestanding network of interconnected nanostructures can be used e.g. in filter devices as filter material or in nanopore-based biosensing systems.

In one embodiment the network of interconnected nanostructures is provided on a substrate. The substrate is preferably selected from the group comprising polymers, polymer films, plastics, plastic films, semiconductor substrates, glasses, oxides, ceramics, metals, metal alloys, metal foils and metal alloy foils. In a preferred embodiment the network of interconnected nanostructures is present at grain boundaries of a polycrystalline film, the film preferably being selected from the group comprising a pure metal film or a metal alloy film, especially a film containing at least one element selected from the group comprising Al, Ti, Cr, Mn, Fe, Co, Ni, Cu, Zn, Zr, Nb, Mo, Pd, Ag, In, Sn, W, Pt, Au and Pb. The network is preferably formed from at least one element selected from the group comprising group III elements (e.g. B, Al, Ga, In), group IV elements (e.g. C, Si, Ge, Sn, Pb), group V elements (e.g. N, P, As, Sb, Bi), O, S, Cu, Zn, Pd, Ag, Pt and Au.

In this connection it should be noted that once the nanostructure(s) has (have) been grown in what was previously the grain boundary, the grain boundary is strictly speaking no longer a grain boundary. A grain boundary is commonly known in the field of materials science as being a boundary between two contacting grains of the same material. However, for the purpose of this application the term grain boundary relates not only to the boundary which is present between contacting grains of a polycrystalline film before the nanostructures have been grown in this boundary, but it is additionally used to describe this boundary also after the nanostructures have been grown therein. For the purpose of this application and to avoid any doubt, the term grain boundary will also be understood to apply to the boundary region between two grains which are not in immediate contact but are only separated by a thin nanostructure of dissimilar materials.

The nanostructures constituting the network are preferably formed by at least first and second layers of different composition, so that by changing the material of the layers, different types of structures can be fabricated. These can comprise one of an n-p structure, a p-n structure, an n-p-n structure, a p-n-p structure optionally with one or more intrinsic material layers between the n-p or p-n layers and optionally in the form of layers of graded composition.

The substrate could then, for example, act as a contact to the nanostructures or be removed to allow a contact to be attached so that it is present in the region where the substrate used to be. In this connection it is preferable when a contact is present at the free surface of the network or of an outermost layer of the network.

It is also advantageous when the network lies generally in a plane having at least first and second regions consisting of different materials or materials with differently selected dopants in each of said first and second regions.

In one further embodiment the network of interconnected nanostructures is a coated network of interconnected nanostructures. Optionally such a coated network of interconnected nanostructures is subjected to a heat treatment step to form a compound nanostructure network composed of the network and the material of the further coating.

In one further embodiment the network of interconnected nanostructures is a surface-functionalized network of interconnected nanostructures. The electric conductivity of such a functionalized network of interconnected nanostructures is sensitive to specific chemical or biological species. One can utilize this sensitivity highly beneficial in sensing applications.

In a further aspect the invention relates to a nanostructure, preferred embodiments of which will be described in the following.

In a yet further aspect the invention relates to an apparatus for manufacturing nanostructures and nanostructure networks. The apparatus comprises at least one vapor source for generating at least a vapor flux of one or more elements which can diffuse into grain boundaries present in a polycrystalline film present on a substrate. An apparatus of this kind can also be equipped with at least two vapor sources one of which is then designated to producing a polycrystalline film and the at least one further vapor source is used to generate the nanostructures. The apparatus can optionally also be provided with an etching station in order to etch away the polycrystalline film once the nanostructures have been grown therein.

Such an apparatus can be installed in a production facility producing roll to roll metallized polymer films e.g. in the packing industry or the thin-film solar cell industry, for example, to produce metallized polymer films reinforced with nanostructures in order to obtain reinforced packaging or high strength polymer films. When including an additional etching station, the apparatus can be used for large-volume roll-to-roll production of nanostructures and nanostructure network on polymer webs.

The invention will be described in detail by way of example only and with reference to embodiments and to the drawings which show:

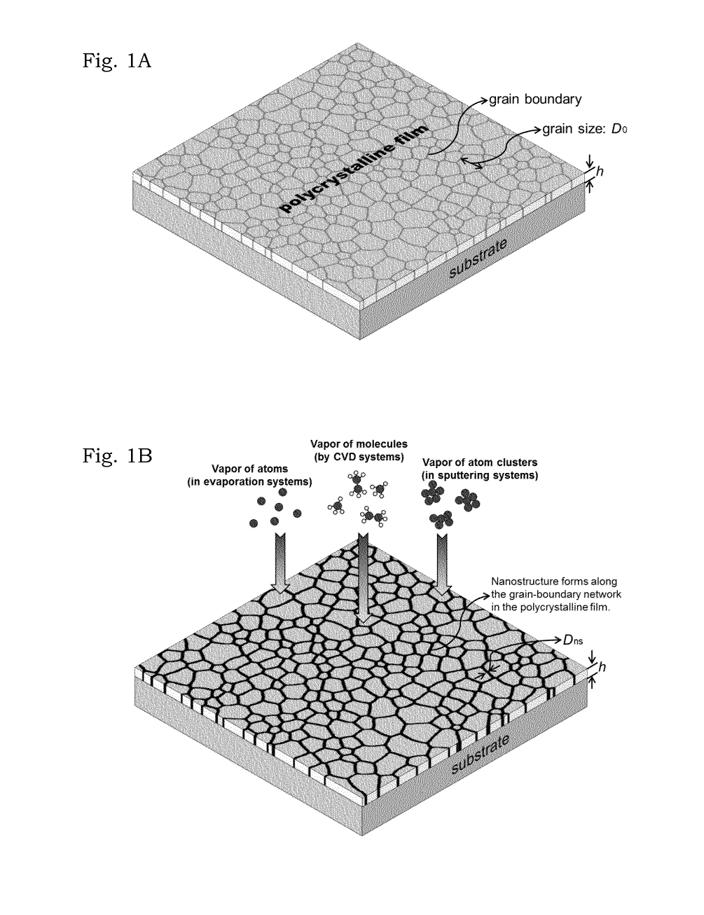

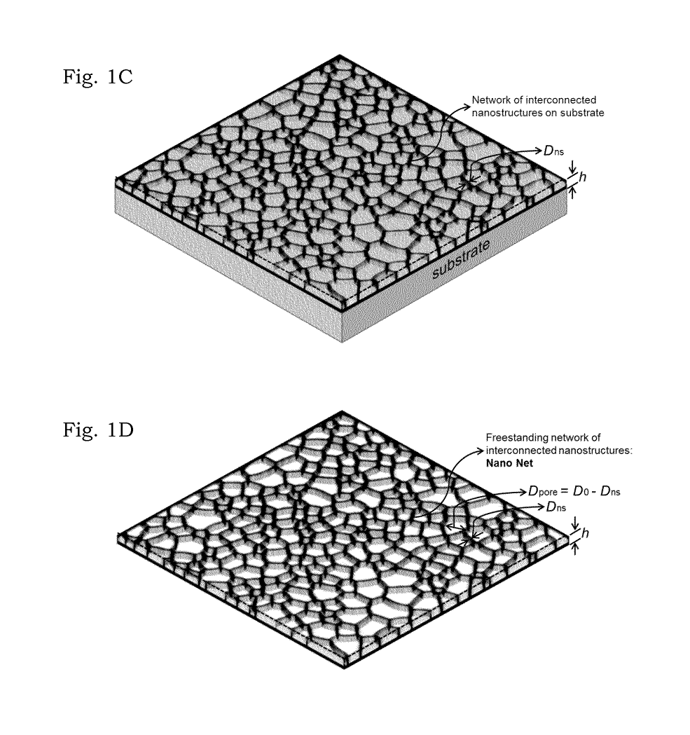

FIGS. 1A-D a schematic illustration of the method in accordance with the invention;

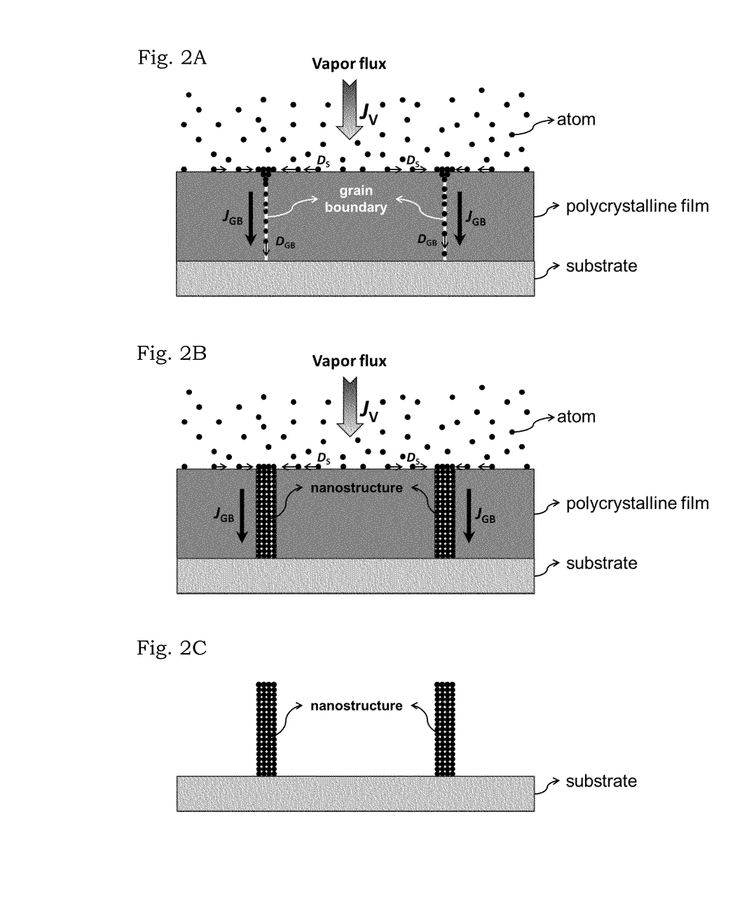

FIGS. 2A-C a schematic cross-sectional view of the process of nanostructure growth in the grain boundaries of a polycrystalline film in accordance with FIGS. 1A to 1D;

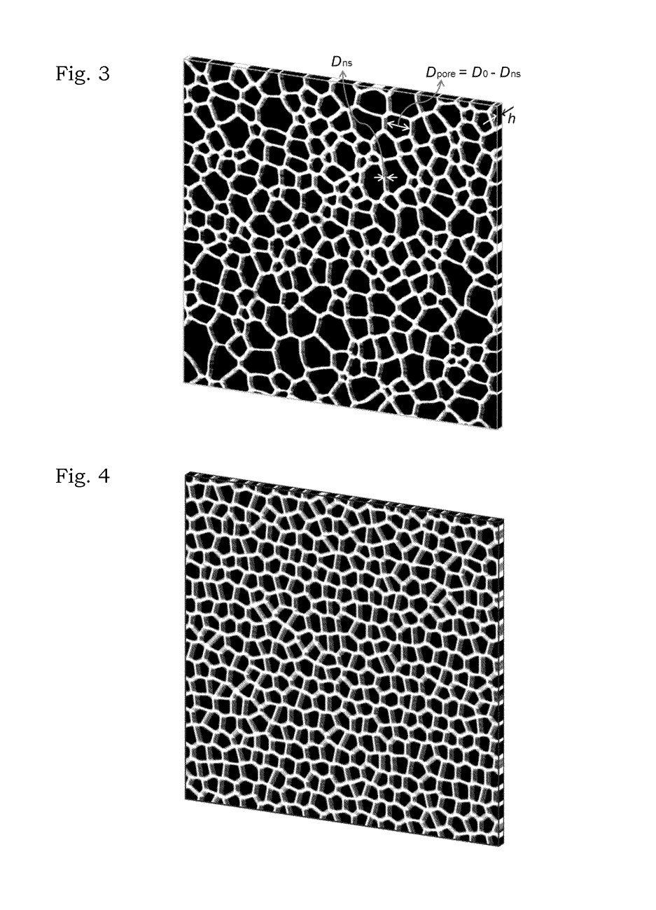

FIG. 3 a schematic illustration of an ultrathin porous membrane (a nano net) which is in the form of a network of interconnected nanostructures;

FIG. 4 a schematic illustration of another ultrathin porous membrane (a nano net) which is in the form of a network of interconnected nanostructures;

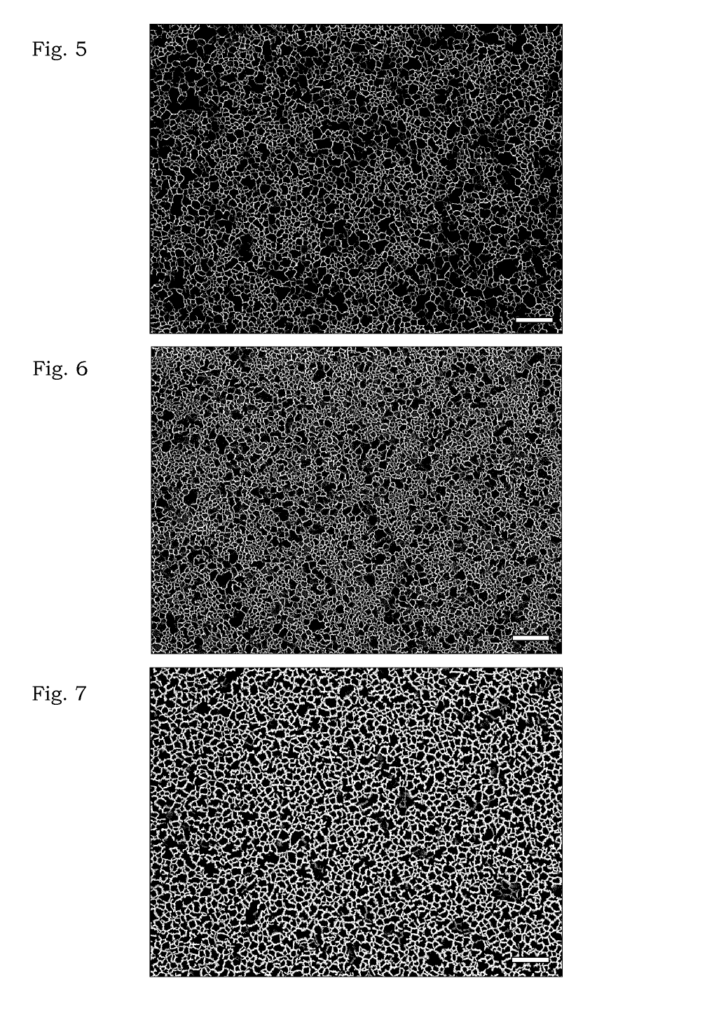

FIG. 5 a top-view scanning electron microscopy image or micrograph (scale bar: 1 μm) of a silicon nanostructure network produced according to the method of FIGS. 1A to 1D;

FIG. 6 a further top-view scanning electron microscopy image or micrograph (scale bar: 1 μm) of a silicon nanostructure network;

FIG. 7 a further top-view scanning electron microscopy image or micrograph (scale bar: 1 μm) of a silicon nanostructure network;

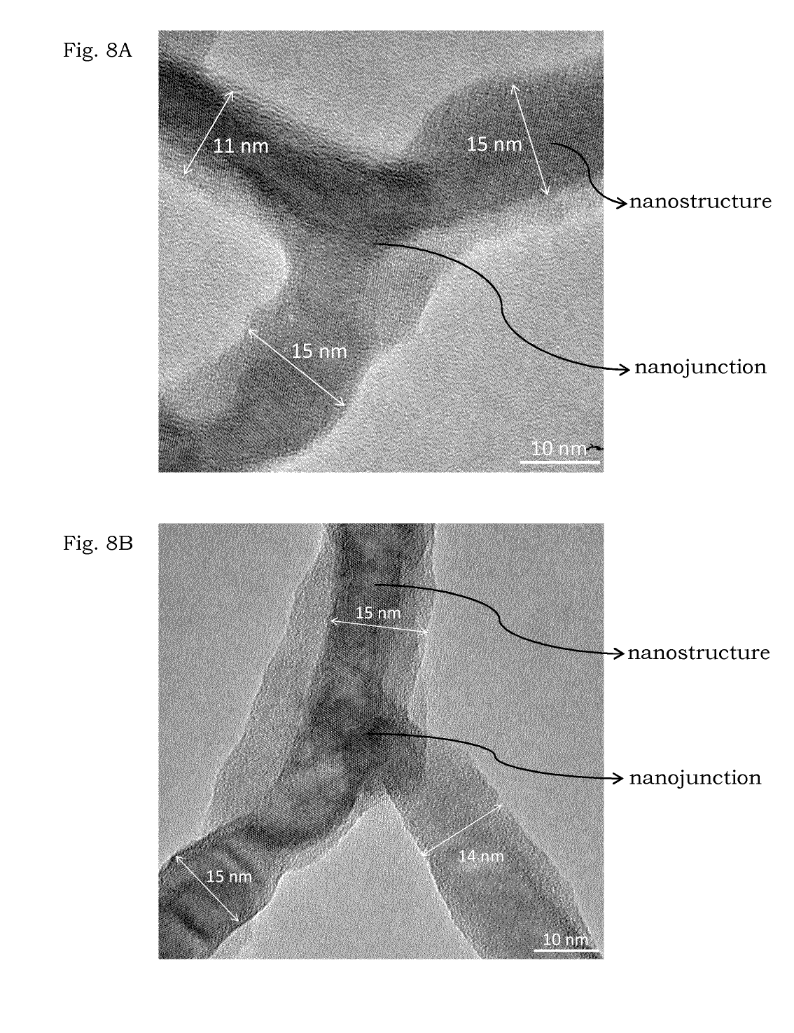

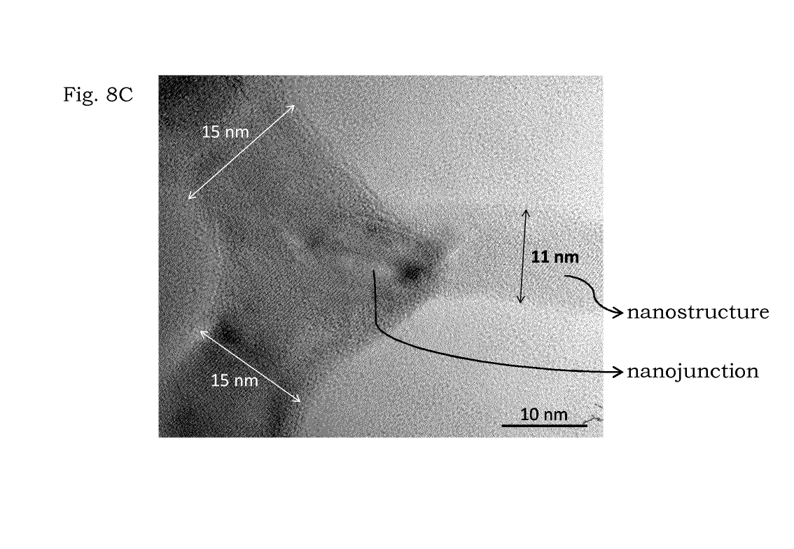

FIGS. 8A-C plan-view high-resolution transmission electron microscopy (HRTEM) micrographs of small parts of a network of interconnected silicon nanostructures;

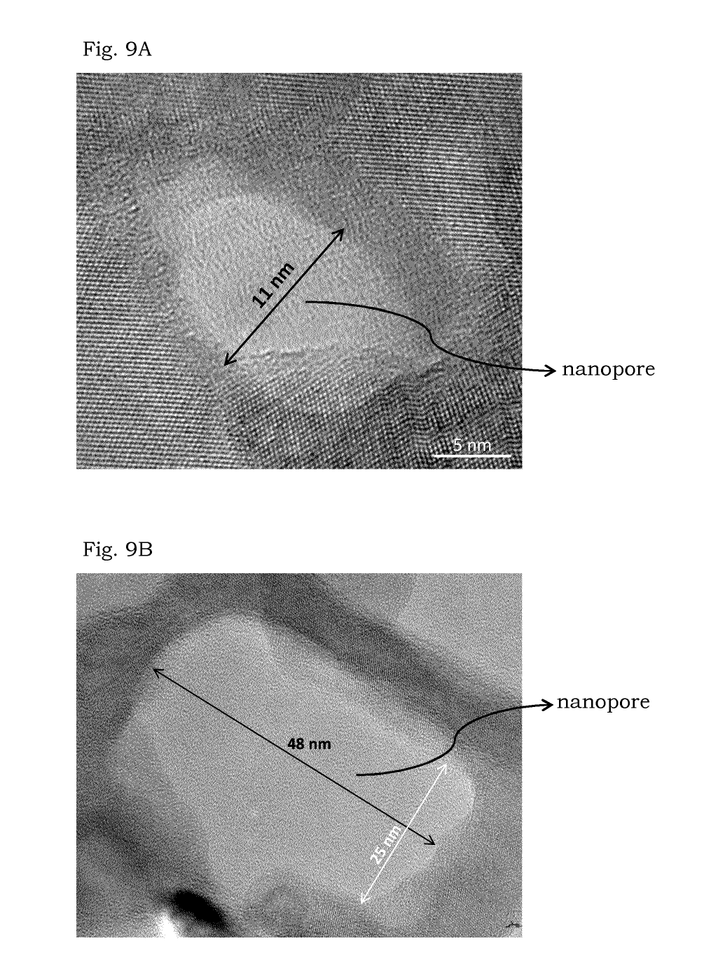

FIGS. 9A-B plan-view HRTEM micrographs of further small parts of a network of interconnected silicon nanostructures;

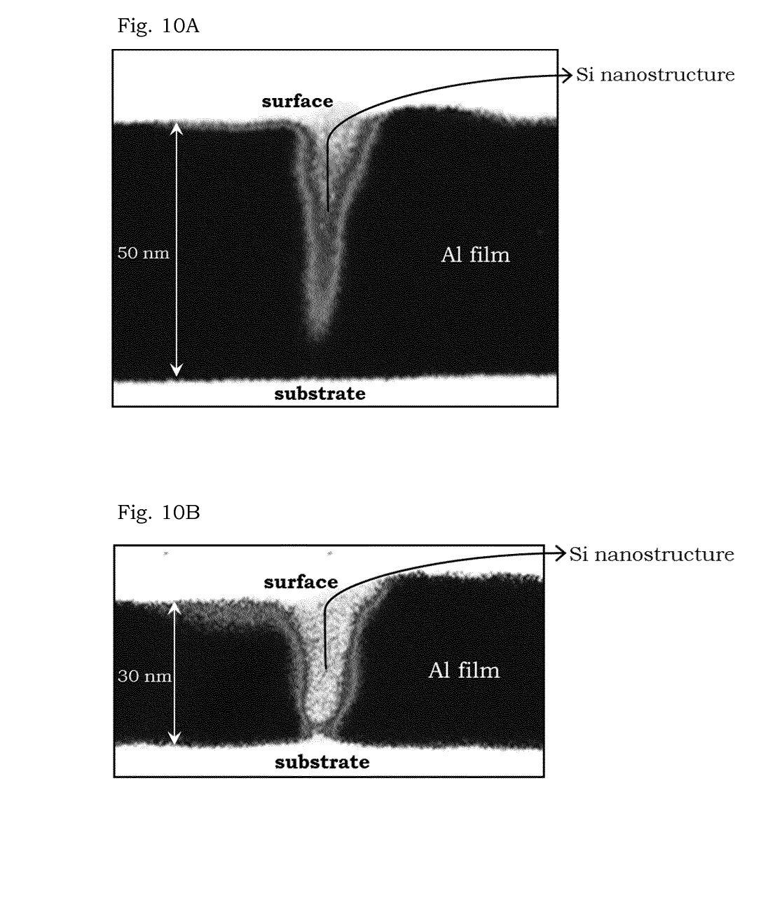

FIG. 10A a cross-sectional plasmon-loss energy mapping of a specimen (light-grey: Si, black: Al);

FIG. 10B a cross-sectional plasmon-loss energy mapping of a specimen (light-grey: Si, black: Al);

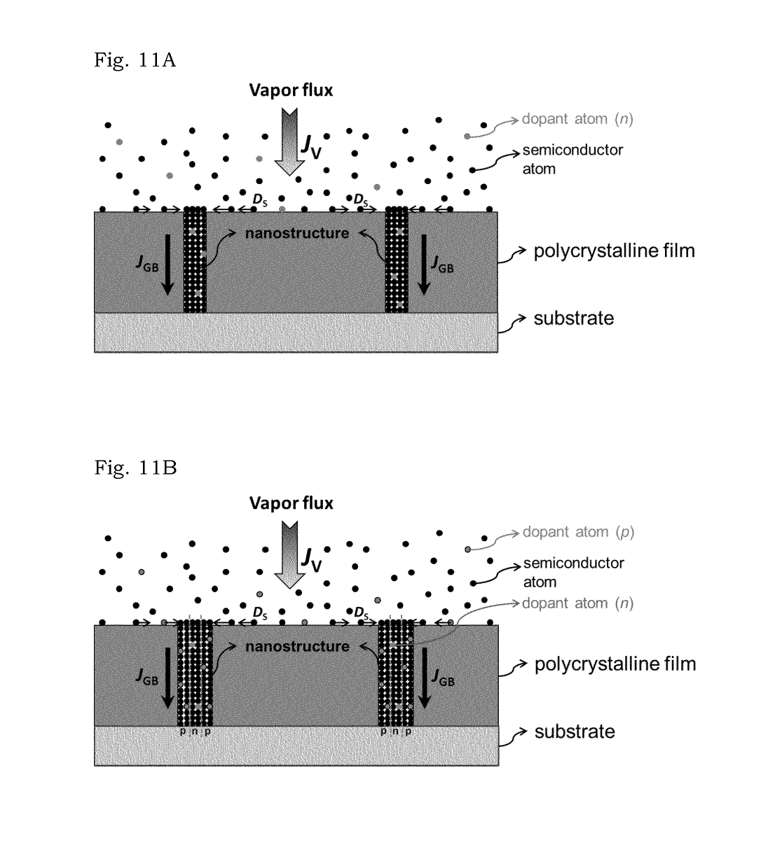

FIG. 11A a schematic illustration (from a cross-sectional view) of the method for doping the semiconductor nanostructures during their growth;

FIG. 11B a schematic illustration (from a cross-sectional view) of the method for the growth of nanostructures and nanostructure networks comprising dopant-modulated heterostructures;

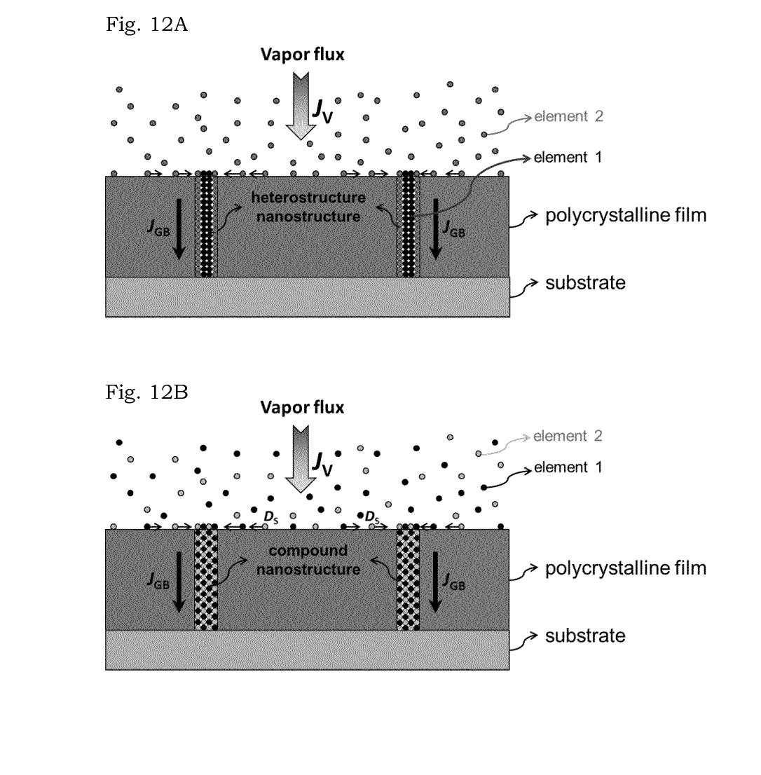

FIG. 12A a schematic illustration (from a cross-sectional view) of the method for the growth of nanostructures and nanostructure networks comprising composition-modulated heterostructures;

FIG. 12B a schematic illustration (from a cross-sectional view) of the method for the growth of alloy (e.g. Si.Ge₁₋ₓ) and compound (e.g. GaAs, SiC) nanostructure and nanostructure networks;

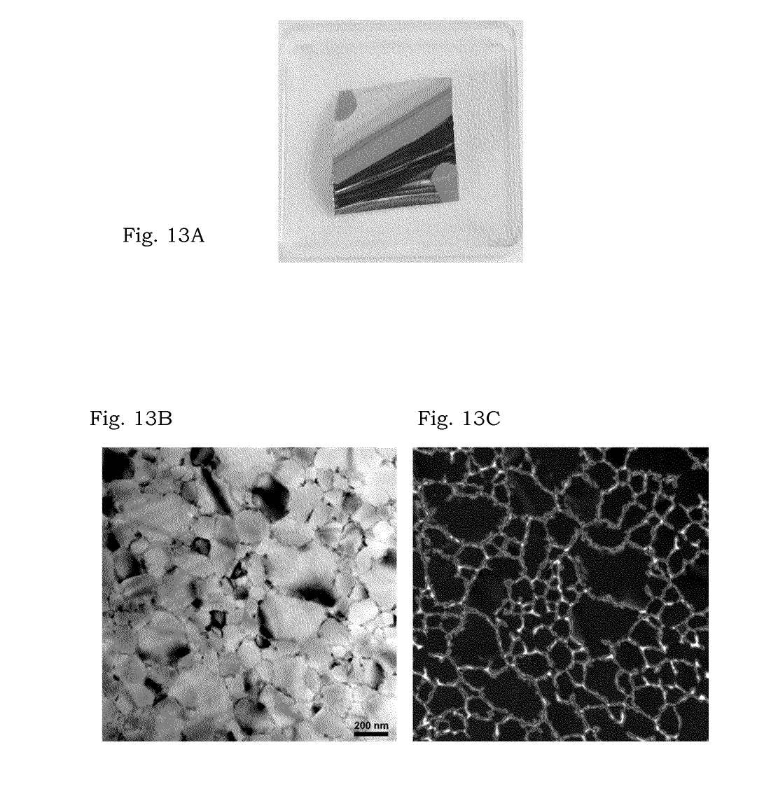

FIGS. 13A-C a Kapton film coated with a polycrystalline aluminium film (50-nm thick) in which the original grain boundary network is occupied by a silicon nanostructure network as produced according to the method of the present invention (FIG. 13A), FIG. 13B shows a bright field transmission electron microscopy image of a 50-nm thick polycrystalline aluminum film in which the original grain boundary network is occupied by a silicon nanostructure network as produced according to the method of the present invention and FIG. 13C shows a plasmon-loss energy mapping (light-grey: Si, black: Al) of FIG. 13B;

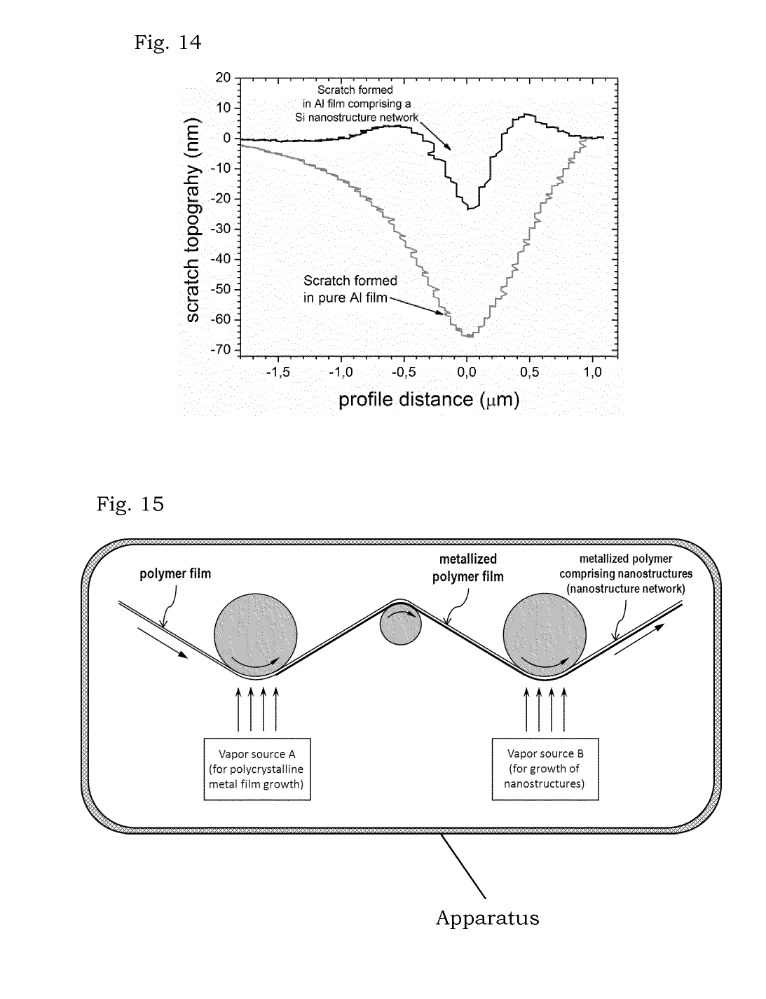

FIG. 14 nanoscratch test results of (i) a 50-nm pure Al film on a 50-nm SiO₂/Si(100) substrate, and (ii) a reinforced 50-nm Al film containing a network of interconnected Si nanostructures on a 50-nm SiO₂/Si(100) substrate; and

FIG. 15 a schematic view of an apparatus which can be used for the industrial production of the nanostructures and nanostructure network described herein.

FIGS. 1A to D show a schematic illustration of the described method for the production of nanostructures and nanostructure networks: FIG. 1A shows a polycrystalline thin film with a columnar grain structure on a solid substrate. FIG. 1B shows that the polycrystalline film on the substrate is exposed to a vapor which contains source materials. During the exposure to a vapor, nanostructures grow along the grain boundary network in the polycrystalline thin film. As a result, a practically complete network of interconnected nanostructures forms in the polycrystalline film. FIG. 1C shows that the original polycrystalline film is selectively etched off, thus leaving a complete network of interconnected nanostructures standing on the substrate. FIG. 1D shows that the substrate is further etched off or detached from the nanostructure network, thus forming a freestanding nanostructure network (also referred to as a nanowire nanomembrane, or a nano net).

FIGS. 2A to C show a schematic cross-sectional view of the process of nanostructure growth in the grain boundaries of a polycrystalline film: FIG. 2A shows that upon exposure of the polycrystalline film to the vapor, atoms from the vapor diffuse along the polycrystalline film surface towards the grain boundaries and subsequently diffuse along the grain boundaries into the polycrystalline film. FIG. 2B shows that the accumulation of the diffused atoms at the grain boundaries in the polycrystalline film leads to the formation of nanostructures at the grain boundaries. FIG. 2C shows that nanostructures are left standing freely on the substrate after selectively etching off the original polycrystalline film.

For reasons of clarity the schematic illustrations shown in FIGS. 2B to 2C and 11A to 12B have been shown as comprising nanostructures which have a width of approximately 4 to 6 atomic layers. In reality the nanostructures grown can however have a width typically in the range of from 1 to 100 nm.

FIG. 3 shows a schematic illustration of an ultrathin porous membrane which is in the form of a network of interconnected nanostructures (nano net). The membrane can be prepared by the method described in the present invention (see also FIGS. 1A to 1D). A membrane manufactured accordingly has an exceptionally high (nano)pore density (typically in the range of 1×10⁹ to 1×10¹¹ pores cm⁻²) and is ultrathin (as thin as 5 nm). The thickness of such membranes generally ranges from 5 to 1000 nm and preferably ranges from 5 to 100 nm.

FIG. 4 shows a schematic illustration of another ultrathin porous membrane which is in the form of a network of interconnected nanostructures. This membrane has a much sharper nanopore size distribution as compared to the ultrathin porous membrane shown in FIG. 3 and can be prepared by the method described in the present invention when using a polycrystalline film with a sharp grain-size distribution.

In the following a method for large-scale, cost-effective production of nanostructures and nanostructure networks will be described. The method enables a nanostructure production temperature of no higher than 600° C. (typically ambient temperature to 200° C.) while using cheap source materials. The method is compatible with major equipment and facilities in current industries allowing a large scale fabrication of nanostructures to take place. Also described are ultrathin porous membranes which are in the form of a network of interconnected nanostructures. Such membranes have exceptionally high (nano)pore density and are ultrathin. The membranes can be produced by the method described in the present invention.

FIGS. 1A to 1D illustrate a method for the production of nanostructures and networks of interconnected nanostructures, the method comprising the following steps in sequence:

A solid substrate is introduced into a thin film growth apparatus. The substrate can be any material in a solid form, such as polymers, polymer films, plastics, plastic films, semiconductor substrates, glasses, oxides, ceramics, metals, metal alloys, metal foils and metal alloy foils. The substrate can also be present in a variety of geometries, such as flat substrates, curved substrates, and even cylinders/pipes (inner side, or outer side, or both sides serving as the substrate).

Following this a polycrystalline thin film is grown on the substrate (see FIG. 1A). The polycrystalline film can be Al, Ti, Cr, Mn, Fe, Co, Ni, Cu, Zn, Zr, Nb, Mo, Pd, Ag, In, Sn, W, Pt, Au and Pb, as well as any alloys/compounds containing at least one element of them. As a method of growing the polycrystalline thin film the following growth methods can be utilized, growth by evaporation deposition, growth by sputtering deposition, growth by chemical vapour deposition, growth by electroplating, or growth by electroless plating. Generally speaking growth parameters should be chosen so that the grown thin film is polycrystalline preferably with a columnar grain structure (see FIG. 1A), which in practice is the most common microstructure observed in metal or metal alloy thin films. The thickness of the polycrystalline thin film (h) is in the range of 5 nm to 1000 nm. The average grain size (D₀) and the grain-size distribution of the polycrystalline film can be tailored by adjusting the growth parameters (growth temperature, growth rate, etc.), and/or by thermal, mechanical, or plasma treatment of the polycrystalline film after its growth. The average grain size (D₀) is preferably in the range of 5 nm to 2000 nm.

Following the growth (provision) of a polycrystalline film on the substrate this is exposed to a vapor which includes source materials e.g. a semiconductor source material, such as silicon and germanium, either at the ambient temperature or at an elevated substrate temperature ranging from ambient temperature to 600° C. This process can be carried out in an evaporation deposition system, or in a chemical vapor deposition system, or in a sputtering deposition system. As shown schematically in FIG. 1B, depending on which type of growth systems is used, the source vapor is supplied to the polycrystalline film surface in the form of atoms (in an evaporation deposition system), or molecules such as silane and germane (in a CVD system), or clusters of atoms (in a sputtering deposition system).

Following the exposure of the polycrystalline film to the vapor (see above), nanostructures grow along the grain boundaries in the polycrystalline film (see FIG. 1B). The process is also schematically shown in FIGS. 2A to 2B in a cross-sectional view. The atoms adsorbed (or formed by first adsorption, and then decomposition of molecules and clusters) at the polycrystalline film surface from the vapor diffuse into the grain boundaries in the polycrystalline film (FIG. 2A), accumulate there and form nanostructures (FIG. 2B). Care needs to be taken to keep the atomic flux supplied by the vapor (J_{V}) in balance with the (maximum) atomic flux along the grain boundaries in the polycrystalline film (ΣJ_{GB}, see FIG. 2B); otherwise a layer growth above the polycrystalline film would occur, which hinders the further growth of nanostructures along grain boundaries in the polycrystalline film.

As a result a network of interconnected nanostructures forms along the grain-boundary network in the polycrystalline film, as schematically shown in FIG. 1B. The average width of the nanostructures (Dₙₛ) is controlled by the vapor exposure time, which increases with increasing exposure time, whereas the height of the nanostructures is solely determined by the polycrystalline film thickness (h), i.e. the height of the nanostructures is the same as the thickness of the polycrystalline film. The total length of the nanostructures constituting the nanostructure network is practically the same as the net length of the original grain-boundary network in the polycrystalline film before exposure to a vapor, and is thus controlled by the original grain-boundary density in the polycrystalline film.

The polycrystalline film can be selectively etched off, thus leaving a network of interconnected nanostructures standing on the substrate, as schematically shown in FIG. 1C. The thereby produced network of interconnected nanostructures can then be utilized in a diverse range of advanced technologies.

Optionally, the network of the interconnected nanostructures can further be separated from the substrate, e.g. by selectively etching away the substrate or by detaching the nanostructure network from the substrate (in this case, the substrate can be reused for next growth), thus forming a freestanding network of interconnected nanostructures, as is schematically shown in FIG. 1D. The freestanding network of interconnected nanostructures can then be transferred to other support structures for desired functionalities and applications. Alternatively, such a freestanding network of interconnected nanostructures itself serves as an excellent ultrathin porous membrane with an exceptionally high and tailorable pore density, and tailorable pore sizes.

Optionally the network of interconnected nanostructures standing on the substrate or the freestanding network of interconnected nanostructures (composed of e.g. Si) can be coated with a further coating e.g. of Ag and having a thickness of about 20 nm by means of a PVD or a plating method. Because the overall geometry of the conductive Ag coating adopts that of the network of interconnected nanostructures, a transparent conductive network of interconnected nanostructures is thus formed. Such a transparent conductive network of interconnected nanostructures can be used as a transparent electrode in solar cells or displays.

The Si mentioned above can be exchanged for a different material containing at least one element selected from B, Al, Ga, In, C, Ge, Sn, Pb, N, P, As, Sb, Bi, O, S, Cu, Zn, Pd, Ag, Pt and Au. Likewise the coating can be selected from the group of materials comprising Ag, Au, Al, Cu, graphite, graphene, Pd, Pt, Ni, Ti, Co, W, Zr, Hf, Ta, Mo. The typical layer thickness for such coatings is selected in the range of 5 to 500 nm, preferably in the range of 5 to 100 nm and especially in the range of 10 to 50 nm. Optionally a heat treatment step at a temperature in the range of 100-700° C. can be applied in order to allow a reaction between the original nanostructure network (of e.g. Si) and the material of the further coating (of e.g. Ni). This reaction thus brings about the formation of a compound (of e.g. NiSi) nanostructure network, which can be used as a transparent electrode in solar cells or displays.

Optionally the network of interconnected nanostructures standing on the substrate or the freestanding network of interconnected nanostructures (of e.g. Si) are functionalized by subjecting them to e.g. a solution of 3-aminopropyltriethoxysilane (APTES) for 30 minutes. Such APTES-modified Si nanostructure network can be used for pH sensing of liquids. Similarly, the nanostructure network can be functionalized with different chemical layers (e.g. amino-silanes, alkane-silanes, or aldehyde-silanes), biological receptors (e.g. biotin, antibodies), or metal (e.g. Ag, Pd, Pt) nanoparticles, for applications as gas, chemical or biological sensors.

The above described method enables the production of nanostructures and nanostructure networks at a low temperature (typically at ambient temperature to 200° C.). The method is compatible with major industrial equipment and facilities (such as a vacuum evaporator, a CVD system, a sputtering deposition system). A substantial decrease in the production cost of nanostructures is expected from the described method. Furthermore, the method is capable of providing extremely accurate controls over the structure/morphology of the produced nanostructures and nanostructure networks, which are summarized as follows:
i. Through controlling the vapor flux and the vapor exposure time, the width of the nanostructures (Dₙₛ) can be tailored.
ii. Through controlling the thickness of the polycrystalline film, the height of the nanostructures (h) can be tailored.
iii. Through controlling the composition of the introduced vapor mixtures, the composition of the nanostructures can be tailored.
iv. Through alternating the type/composition of the introduced vapor mixtures, nanostructures comprising heterostructures can be prepared.
v. Through controlling the grain structure of the polycrystalline film (e.g. grain sizes and grain-size distributions), the morphology of the nanostructure network can be tailored.
vi. The production of nanostructures and nanostructure networks can be carried out on a variety of substrates made of various (in particular, heat-sensitive) materials and with different geometries. A very interesting application is, for example, the production of nanostructures and nanostructure networks within slim plastic pipes.

In order to prepare ultrathin porous membranes which are in the form of networks of interconnected nanostructures (nanowire nanomembranes, or nano nets), the above described method is utilized. The structure of such an ultrathin porous membrane is demonstrated schematically in FIG. 1D and in FIG. 3 from two different perspectives. The ultrathin porous membrane has exceptionally high (nano)pore density and (nano)pore sizes which can be tailored, and can be made extremely thin (as thin as 5 nm). The thickness (h) of such an ultrathin porous membrane is preferably in the range of 5 nm to 1000 nm. The average nanostructure width (Dₙₛ) is preferably in the range of 1 nm to 50 nm, and the average pore size (Dₚₒᵣₑ) is preferably in the range of 1 nm to 1000 nm. The ultrathin porous membrane can be made of an element, or a compound, or a solid solution, or an alloy containing at least one element selected from group III elements (e.g. B, Al, Ga, In), group IV elements (e.g. C, Si, Ge, Sn, Pb), group V elements (e.g. N, P, As, Sb, Bi), O, S, Cu, Zn, Pd, Ag, Pt and Au.

The above-mentioned parameters (h, Dₙₛ, Dₚₒᵣₑ as well as the composition and geometry) of the ultrathin porous membrane can be tailored by using the method described above. In particular, the pore size (Dₚₒᵣₑ) is equal to D₀−Dₙₛ, where D₀ is the grain size in the original polycrystalline film. Thus the average pore size as well as the pore-size distribution of the ultrathin porous membrane can be well tailored by tuning the average grain size and the grain-size distribution of the used polycrystalline film, as well as the Dₙₛ. For a polycrystalline film, it is possible to tailor its grain structure (grain size and grain size distribution), for example, by controlling its growth parameters (such as substrate, growth rate, growth temperature), and/or by further thermal, mechanical or plasma treatment after its growth. Nanostructure networks with different morphologies can be prepared by using polycrystalline films with different grain structures. The simplest form of manipulation of a grain structure takes place by implementing a heat treatment step, in which the polycrystalline film is heated to e.g. a temperature in the range of 100 to 600° C. which causes grain growth to occur in the polycrystalline film (C. V. Thompson, Annu. Rev. Mater. Sci. 1990, 20:245-68) leading to a different grain structure of the polycrystalline film as compared to that prior to the step of heat treatment.

FIG. 4 schematically shows an ultrathin porous membrane with a sharp pore-size distribution when compared to FIG. 3. The sharp pore size distribution can be prepared by using a polycrystalline film having a sharp grain-size distribution.

The advantages discussed above of the ultrathin porous membrane having an ultrahigh pore density and a tailorbale nanopore size obtainable at a low production cost and with a flexible geometry makes these ultrathin porous membranes utilizable in a diverse range of applications, for example, in ultrafiltration/nanofiltration devices or in nanopore-based biosensing systems. In particular, since silicon is well-known to be a non-toxic and biodegradable material, silicon nanowire nanomembranes (or nano nets) are especially suitable for applications in medical devices and water purification devices.

The following examples are provided to illustrate embodiments of the present invention but are by no means intended to limit its scope.

FIG. 5 shows a top-view scanning electron microscopy micrograph of a network of interconnected silicon nanostructures which was produced according to the steps and parameters given in example 1 below. The scale bar indicates 1 μm.

In example 1 a silicon nanostructure network was produced according to the method of the present invention. The detailed steps and parameters are described as follows:
1. A flat Si(100) wafer covered with 50-nm thermally grown SiO₂ film was used as a substrate. The substrate was ultrasonically cleaned in acetone and in isopropanol in sequential steps, following which the substrate was introduced into a multisource evaporation growth chamber.
2. A 50-nm thick aluminium film was grown on the substrate by thermal evaporation. The substrate temperature was kept at room temperature and the growth rate was 5.9 nm/min. The growth time was 506 seconds.
3. The aluminium film on the substrate was heated to approximately 90° C. (as determined by a type-K thermocouple put behind the substrate), and then exposed to a flux of silicon atoms (Si vapor) of 3.0×10⁻⁶ mol·m⁻²·s⁻¹ generated from an effusion cell containing pure silicon. The exposure time was 210 seconds.
4. After the exposure, the specimen was cooled down to room temperature, and then taken out of the growth chamber.
5. The aluminium was selectively etched away from the specimen by putting the specimen into an aluminium etchant solution (Type ANPE 80/5/5/10, available from MicroChemicals) for 120 seconds at room temperature.

By means of this process, a network of interconnected silicon nanostructures was produced on a 50-nm SiO₂ substrate. The nanostructure network has a thickness (h) of 50 nm, an average nanostructure width (Dₙₛ) of approximately 14 nm, a dominant nanopore size (Dₚₒᵣₑ) of approximately 60 nm, a mean nanopore size of approximately 100 nm and a nanopore density higher than 7×10⁹ pores cm⁻². This can be seen in the top-view scanning electron microscopy (SEM) micrograph of the produced silicon nanostructure network shown in FIG. 5.

FIG. 6 shows a further top-view scanning electron microscope image or micrograph of the silicon nanostructure network which was produced according to the steps and parameters given in Example 2 below. Also in this case the scale bar indicates a size of 1 μm.

In example 2 a further silicon nanostructure network was produced according to the method given in the present invention. The detailed steps and parameters are described as follows:
1. A flat Si(100) wafer covered with 50-nm thermally grown SiO₂ film was used as substrate. The substrate was ultrasonically cleaned in acetone and isopropanol sequentially, and then introduced into a multisource evaporation growth chamber.
2. A 30-nm thick aluminium film was grown on the substrate by thermal evaporation. The substrate temperature was kept at room temperature and the growth rate was 5.9 nm/min. The growth time was 300 seconds.
3. The aluminium film on the substrate was heated to approximately 90° C. (as determined by a type-K thermocouple put behind the substrate), and then exposed to a flux of silicon atoms (Si vapor) of 3.0×10⁻⁶ mol·m⁻²·s⁻¹ generated from an effusion cell containing pure silicon. The exposure time was 210 seconds.
4. After the exposure, the specimen was cooled down to room temperature, and then taken out of the growth chamber.
5. The aluminium was selectively etched away from the specimen by putting the specimen into an aluminium etchant solution (Type ANPE 80/5/5/10, available from MicroChemicals) for 120 seconds at room temperature.

By means of this process, a network of interconnected silicon nanostructures was produced on a 50-nm SiO₂ substrate. The nanostructure network has a thickness (h) of 30 nm, an average nanostructure width (Dₙₛ) of approximately 18 nm, a dominant nanopore size (Dₚₒᵣₑ) of approximately 40 nm, a mean nanopore size of approximately 75 nm and a nanopore density higher than 1×10¹⁰ pores cm⁻². This can be seen in the top-view SEM micrograph of the produced silicon nanowire network shown in FIG. 6.

FIG. 7 shows a further top-view scanning electron microscope image or micrograph of the silicon nanostructure network which was produced according to the steps and parameters given in Example 3 below. Also in this case the scale bar indicates a size of 1 μm.

In example 3 a third silicon nanostructure network was produced according to the method given in the present invention. The detailed steps and parameters are described as follows:
1. A flat Si(100) wafer covered with 50-nm sputtering-grown Si₃N₄ film was used as substrate. The substrate was ultrasonically cleaned in acetone and isopropanol sequentially, and then introduced into a multisource evaporation growth chamber.
2. A 50-nm thick aluminium film was grown on the substrate by thermal evaporation. The substrate temperature was kept at room temperature and the growth rate was 1.0 nm/min. The growth time was 50 minutes.
3. The aluminium film on the substrate was heated to approximately 90° C. (as determined by a type-K thermocouple put behind the substrate), and then exposed to a flux of silicon atoms (Si vapor) of 3.0×10⁻⁶ mol·m²·s⁻¹ generated from an effusion cell containing pure silicon. The exposure time was 210 seconds.
4. After the exposure, the specimen was cooled down to room temperature, and then taken out of the growth chamber.
5. The aluminium was selectively etched away from the specimen by putting the specimen into an aluminium etchant solution (Type ANPE 80/5/5/10, available from MicroChemicals) for 120 seconds at room temperature.

By means of this process, a network of interconnected silicon nanostructures was produced on a 50-nm Si₃N₄ substrate. The nanostructure network has a thickness (h) of 50 nm, an average nanostructure width (Dₙₛ) of approximately 30 nm, a dominant nanopore size (Dₚₒᵣₑ) of approximately 95 nm, a mean nanopore size of approximately 125 nm and a nanopore density higher than 3×10⁹ pores cm⁻². The network of interconnected nanostructures can clearly be seen in the top-view SEM micrograph of FIG. 7.

FIGS. 8A to 8C show plan-view high-resolution transmission electron microscopy (HRTEM) micrographs of parts of a network of interconnected silicon nanostructures. The HRTEM micrographs were taken using a JEOL 4000FX transmission electron microscope operated at 400 kV. The network of interconnected nanostructures was produced according to the steps and parameters given in example 1. From the observed crystal lattice fringes in the HRTEM micrographs of the Si nanostructures, it can be seen that the produced network of interconnected silicon nanostructures are crystalline. The observed nanostructure width (Dₙₛ) is in the range of about 11-15 nm.

FIGS. 9A and 9B show plan-view HRTEM micrographs of further parts (each containing a nanopore surrounded by the interconnected nanostructures) of the network of interconnected silicon nanostructures. The network of interconnected nanostructures shown was produced according to the steps and parameters given in example 1. A nanopore with a characteristic size of only about 11 nm is clearly observable in FIG. 9A, which is surrounded by crystalline Si nanostructures (see the lattice fringes therein). A larger nanopore with a characteristic size of about 25 nm×48 nm is revealed in FIG. 9B, which is also surrounded by crystalline Si nanostructures.

FIG. 10A shows the cross-sectional plasmon-loss energy mapping (light-grey: Si, black: Al; acquired using a Zeiss SESAM transmission electron microscope operated at 200 kV) of a specimen prepared according to the steps and parameters given in example 1, however, the final step of etching off Al has been omitted (i.e. step 5 was not carried out). It clearly demonstrates that a silicon nanostructure has been formed exclusively within the 50-nm thick Al film.

FIG. 10B shows a cross-sectional plasmon-loss energy mapping (light-grey: Si, black: Al; acquired using a Zeiss SESAM transmission electron microscope operated at 200 kV) of a specimen prepared according to the steps and parameters given in example 2, however, the final step of etching off Al has been omitted (i.e. step 5 was not carried out). It demonstrates that a silicon nanostructure has been formed exclusively within the 30-nm thick Al film.

FIG. 11A shows a schematic illustration of the method for doping the semiconductor nanostructures and nanostructure networks during their growth. This is achieved by introducing a certain amount of dopant vapor (for example, n-type dopant) together with the semiconductor source vapor. FIG. 11B shows a schematic illustration of the method for the growth of semiconductor nanostructures and nanostructure networks comprising dopant-modulated heterostructures (for example, p-n-p junctions). This is achieved by alternating the concentrations and types of the dopant vapor introduced (here, e.g. introducing p-type dopant after introducing n-type dopant).

FIG. 12A shows a schematic illustration of the method for the growth of nanostructures and nanostructure networks comprising composition-modulated heterostructures (e.g. Si/Ge heterojunction). In the present example this is achieved by alternating the composition of the vapor introduced. FIG. 12B shows a schematic illustration of the method for the growth of alloy (e.g. SiₓGe₁₋ₓ) and compound (e.g. GaAs, SiC) nanostructures and nanostructure networks. Such nanostructures and nanostructure networks have a tailorable composition which is achieved through the simultaneous introduction of different types of vapor with different flux ratios.

FIG. 13A shows a Kapton film coated with a 50-nm thick polycrystalline aluminium film (i.e. an aluminized Kapton film) in which a Si nanostructure network having been formed along the grain boundary network of the aluminium film. FIG. 13B shows a bright field transmission electron microscopy (TEM) micrograph of a 50-nm thick polycrystalline aluminum film which has been exposed to a silicon vapor flux at about 90° C. according to the method of the present invention and FIG. 13C shows a plasmon-loss energy mapping of FIG. 13B. The TEM analyses were carried out in a Zeiss SESAM transmission electron microscope operated at 200 kV. The TEM analyses show that the original grain boundary network in the Al film is now completely covered by about 10 nm wide Si nanostructures which form a network of interconnected nanostructures. Thereby an aluminized Kapton film can be produced having enhanced mechanical properties including hardness, modulus, stiffness and wear resistance with respect to normally aluminized Kapton films due to the application of the method in accordance with the invention.

FIG. 14 shows nanoscratch test results of (i) a 50-nm pure Al film on a 50-nm SiO₂/Si(100) substrate, and (ii) a reinforced 50-nm Al film on a 50-nm SiO₂/Si(100) substrate, in which a Si nanostructure network is present. The Si nanostructure network has been formed by exposure of the Al film to Si vapor for 210 s at a substrate temperature of 90° C. (as determined by a type-K thermocouple placed behind the substrate). It follows that the scratch formed in the Al film containing a Si nanostructure network generated according to the method described in this invention is much smaller than that formed in the untreated Al film, under the same nanoscratch conditions. It proves that the method in this invention serves also as a method for producing reinforced (metal) films.

The nanoscratch test was carried out using a MTS Nano-Indenter XP system equipped with a diamond Berkovich tip. On carrying out a test, the tip is moved along the specimen surface over a travel distance of 10 micron at a velocity of 0.5 micron/s and a ramping normal load from 0 to 4 mN. The tip was oriented such that an edge of the Berkovich pyramid was pointing in the direction of travel. The cross profile of the formed nanoscratch at the specimen surface was measured at the location corresponding to a normal load of 2 mN.

FIG. 15 shows a schematic view of an apparatus suitable for low-cost, high-speed, large-volume production of nanostructures and nanostructure networks, as well as nanostructure-reinforced metallized polymer films. The apparatus shown in FIG. 15 includes three rollers which are installed in a system either in different separate chambers or in one large common chamber in order to guide a polymer film (i.e. the substrate, for example, as specified above) from a start region to an end region. In accordance with FIG. 15 the polymer film is guided from left to right as indicated by the arrows.

The rollers are installed to ensure a correct guidance of the polymer film from a polymer film supply (not shown) to a further (non-illustrated) processing station at which a metallized polymer film comprising nanostructures is collected and processed for e.g. packaging purposes or other applications. The rollers may further include a heating or cooling unit optionally with a temperature control, providing necessary heating or cooling of the polymer film (substrate) during production of the nanostructures. As the polymer film is moved from the supply to the processing station it passes a first vapor source e.g. a vapor source for evaporating a metal such as aluminium, which is used to coat the polymer film with the polycrystalline metal film having grain boundaries in order to obtain a metallized polymer film.

A second vapor source is arranged downstream of the first vapor source and provides a vapor flux, such as a Si vapor flux, one or more elements of which diffuse into the grain boundaries in the polycrystalline metal film of the metallized polymer film, so that a metallized polymer film comprising (and thereby reinforced with) nanostructures in the grain boundary network of the polycrystalline metal film is obtained.

The first and the second vapor source can be any known type of vapor source which is suitable for forming e.g. a polycrystalline metal film covering the polymer film and which is/are suitable to produce a vapor flux including at least one element which can diffuse into the grain boundaries of the polycrystalline film. Typical vapor sources include PVD vapor sources, CVD vapor sources, PECVD vapor sources, and effusion gas cells. These require the use of specific chambers, such as vacuum chambers. Such vapor sources are well known per se to the person skilled in the art and for this reason do not need to be explained in detail here.

An apparatus in accordance with FIG. 15 can enable a low temperature, high-speed, and large volume generation of nanostructures and nanostructure networks, which in addition uses cost effective substrates (polymer films) such as PET (e.g. Mylar) and Kapton films, thereby considerably reducing the cost of manufacture of nanostructures. In addition, since thin metal films are reinforced by the nanostructures present at their grain boundary networks, low-cost metallized polymer films reinforced with nanostructures are also generated which means that reinforced films for packaging can now be made on an industrial scale. The second vapor source for generating the vapor flux for growth of nanostructure in the grain boundaries of the polycrystalline films can simply be installed in addition to pilot-line scale facilities available in current packing industry.

The apparatus may optionally further include an etching station arranged downstream of the vapor source for generating the nanostructures and nanostructure networks, either in a separate chamber or in one common chamber together with the vapor source(s). As such the apparatus can be used for high-speed and large-volume production of nanostructures and nanostructure networks on webs of polymer films.

1. A method for the fabrication of nanostructures, comprising the steps of:
a) providing a substrate having a polycrystalline film on at least a surface thereof, wherein the polycrystalline film is a film having grain boundaries;
b) exposing the polycrystalline film to a vapor flux at a temperature equal to or above ambient temperature, wherein at least one element which is included in the vapor diffuses into the grain boundaries of the polycrystalline film resulting in growth of nanostructures at said grain boundaries.

2. A method in accordance with claim 1, wherein the substrate is selected from the group comprising polymers, polymer films, plastics, plastic films, semiconductor substrates, glasses, oxides, ceramics, metals, metal alloys, metal foils and metal alloy foils.

3. A method in accordance with claim 1 or claim 2, wherein the polycyrstalline film is a pure metal or a metal alloy film, preferably containing at least one element selected from the group comprising Al, Ti, Cr, Mn, Fe, Co, Ni, Cu, Zn, Zr, Nb, Mo, Pd, Ag, In, Sn, W, Pt, Au and Pb.

4. A method in accordance with any one of the preceding claims, wherein an average thickness of the polycrystalline film is less than 1000 nm and preferably less than 100 nm and is most preferably greater than or equal to 5 nm.

5. A method in accordance with any one of the preceding claims, wherein the method is carried out at a temperature in the range of ambient temperature to 600° C., and preferably at a temperature in the range of ambient temperature to 350° C.

6. A method in accordance with any one of the preceding claims, wherein the said vapor contains at least one element selected from the group comprising group III elements (e.g. B, Al, Ga, In), group IV elements (e.g. C, Si, Ge, Sn, Pb), group V elements (e.g. N, P, As, Sb, Bi), O, S, Cu, Zn, Pd, Ag, Pt and Au.

7. A method in accordance with any one of the preceding claims, wherein the vapor flux is restricted to below a level at which the material of the vapor is deposited as a film on the free surface of the polycrystalline film.

8. A method in accordance with any one of the preceding claims, wherein, in step b, at least one element included in the vapor flux diffuses into the grain boundaries of the polycrystalline film and reacts with the polycrystalline film to form compound nanostructures or alloy nanostructures at said grain boundaries.

9. A method in accordance with any one of the preceding claims, wherein the method further comprises the step of thermal, mechanical, or plasma treatment of the polycrystalline film before step b.

10. A method in accordance with any one of the preceding claims, wherein, in step b, at least two elements included in the vapor flux diffuse into the grain boundaries of the polycrystalline film resulting in growth of alloy or compound or doped nanostructures at said grain boundaries.

11. A method in accordance with at least one of the preceding claims, wherein, in step b, at least one of the elements diffusing into the grain boundaries is a dopant in the nanostructures formed at said grain boundaries.

12. A method in accordance with any one of the preceding claims, wherein, during step b, the polycrystalline film is sequentially exposed to at least two different types of vapor flux, optionally in the same treatment chamber or in a second treatment chamber.

13. A method in accordance with any one of the preceding claims, wherein the polycrystalline film is selectively masked to define at least a first exposed region and at least one second masked region, a first vapor having a first composition is allowed to be exposed to the polycrystalline film at the first exposed region, the second masked region is at least partly exposed to form a second exposed region and a second vapor having a second composition is allowed to be exposed to the polycrystalline film at the second exposed region.

14. A method in accordance with any one of the preceding claims, wherein the method comprises the step of selectively etching off or removing the said polycrystalline film after step b.

15. A method in accordance with any one of the preceding claims, wherein the method comprises the step of separating said nanostructures from said substrate, e.g. by selectively etching off said substrate, or by detaching the nanostructures from said substrate (in this case, the substrate can be reused for next growth).

16. A method in accordance with claim 14 or claim 15, further comprising the step of providing a further coating on said nanostructures.

17. A method in accordance with claim 16, further comprising the step of subjecting the coated nanostructures to a heat treatment step to form compound nanostructures composed of the nanostructures and the material of the further coating.

18. A method in accordance with any one of the preceding claims 14 to 17, further comprising the step of functionalizing the nanostructures.

19. A network of interconnected nanostructures, in particular formed in accordance with a method of any one of the preceding claims.

20. A network in accordance with claim 19, wherein the network of interconnected nanostructures is a freestanding network of nanostructures.

21. A network in accordance with claim 19, wherein the network of interconnected nanostructures is provided on a substrate.

22. A network in accordance with claim 21, wherein the substrate is selected from the group comprising polymers, polymer films, plastics, plastic films, semiconductor substrates, glasses, oxides, ceramics, metals, metal alloys, metal foils and metal alloy foils.

23. A network in accordance with any one of claims 19 to 22, wherein the network of nanostructures is present at grain boundaries of a polycrystalline film, preferably selected from the group comprising a pure metal film or a metal alloy film, preferably containing at least one element selected from the group comprising Al, Ti, Cr, Mn, Fe, Co, Ni, Cu, Zn, Zr, Nb, Mo, Pd, Ag, In, Sn, W, Pt, Au and Pb.

24. A network in accordance with any one of the preceding claims 19 to 23, wherein the network contains at least one element selected from the group comprising group III elements (e.g. B, Al, Ga, In), group IV elements (e.g. C, Si, Ge, Sn, Pb), group V elements (e.g. N, P, As, Sb, Bi), O, S, Cu, Zn, Pd, Ag, Pt and Au.

25. A network in accordance with any one of the preceding claims 19 to 24, wherein the included nanostructures are formed by at least first and second layers of different composition.

26. A network in accordance with claim 25, wherein said network comprises at least one of an n-p structure, a p-n structure, an n-p-n structure, p-n-p structure optionally with one or more intrinsic material layers between the n-p or p-n layers and optionally in the form of layers of graded composition.

27. A network in accordance with any one of the preceding claims 19 to 26, wherein a contact is present at the free surface of the network or of an outermost layer of the network.

28. A network in accordance with any one of the preceding claims 19 to 27, wherein the network lies generally in a plane having at least first and second regions consisting of different materials or materials with differently selected dopants in each of said first and second regions.

29. A network in accordance with any one of the preceding claims 19 to 28, wherein the network is provided with a further coating.

30. A network in accordance with claim 29, wherein the network is a compound nanostructure network composed of the network and the material of the further coating.

31. A network in accordance with any one of the preceding claims 19 to 30, wherein the network is a functionalized network.

32. A nanostructure in particular formed in accordance with a method of any one of the preceding claims 1 to 18 and preferably having the features of any one of the preceding claims 19 to 31.

33. An apparatus for manufacturing nanostructures, preferably networks of interconnected nanostructures in accordance with at least one of the preceding claims 19 to 31, comprising at least one vapor source for generating at least a vapor flux of one or more elements which diffuse into grain boundaries present in a polycrystalline film present on a substrate.

34. An apparatus in accordance with claim 33, wherein the apparatus comprises at least two vapor sources, wherein one of the vapor sources is adapted to generate a polycrystalline film on the substrate.

35. An apparatus in accordance with claim 33 or claim 34, the apparatus further comprising an etching station.

36. An apparatus in accordance with at least one of the claims 33 to 35, wherein a substrate guide is provided to move the substrate between the at least two vapor sources.

37. An apparatus in accordance with any one of the preceding claims 33 to 36, wherein the apparatus comprises a housing such as an evacuatable chamber containing the at least one vapor source and the substrate.

38. An apparatus in accordance with any one of the preceding claims 33 to 37, the apparatus further including a heater and optionally a temperature control means for maintaining the temperature the substrate in the range of from ambient temperature to 600° C., preferably from ambient temperature to 350° C., most preferably in the range of from ambient temperature to 200° C.
